(19) United States
(12) Patent Application Publication
(10) Pub. No.: US 2026/0277093 A1
(43) Pub. Date: Sep. 17, 2026

(54) REFLECTIVE MASK BLANK, REFLECTIVE MASK, REFLECTIVE MASK BLANK MANUFACTURING METHOD, AND REFLECTIVE MASK MANUFACTURING METHOD

(71) Applicant: AGC Inc., Tokyo (JP)

(72) Inventors: Takeshi TOMIZAWA, Tokyo (JP); Daijiro Akagi, Tokyo (JP)

(73) Assignee: AGC Inc., Tokyo (JP)

(21) Appl. No.: 19/679,121

(22) Filed: May 15, 2026

Related U.S. Application Data
(63) Continuation of application No. PCT/JP2024/039849, filed on Nov. 8, 2024.

(30) Foreign Application Priority Data
Nov. 29, 2023 (JP) 2023-201162

(51) Int. Cl. G03F 1/24; G03F 1/52; G03F 1/54

(52) U.S. Cl. CPC G03F 1/24; G03F 1/52; G03F 1/54

(57) ABSTRACT

A reflective mask blank has a substrate, a multilayer reflective film configured to reflect EUV light, and an absorbing film configured to absorb the EUV light in this order, and has a conductive film on the opposite side of the multilayer reflective film from the substrate. A coefficient of dynamic friction of the conductive film on the surface opposite the substrate is less than 0.45, measured in a nitrogen atmosphere at room temperature.

The present application is a continuation of PCT/JP2024/039849, filed on Nov. 8, 2024, the entire contents of which are incorporated herein by reference.

### TECHNICAL FIELD

The present disclosure relates to a reflective mask blank, a reflective mask, a reflective mask blank manufacturing method, and a reflective mask manufacturing method.

### BACKGROUND ART

In recent years, with the miniaturization of semiconductor devices, EUV lithography (EUVL), an exposure technology using extreme ultraviolet (EUV), has been developed. EUV includes soft X-rays and vacuum ultraviolet light, specifically light with a wavelength of approximately 0.2 nm to 100 nm. At present, EUV with a wavelength of approximately 13.5 nm is the main focus of research.

In EUVL, a reflective mask is used. The reflective mask, for example, has a substrate, a multilayer reflective film, and an absorbing film, in this order. The multilayer reflective film reflects EUV light. The absorbing film absorbs EUV light. The absorbing film not only absorbs EUV light but may also shift the phase of the EUV light. That is, the absorbing film may be a phase shift film. In EUVL, an opening pattern of the absorbing film is transferred to a target substrate, such as a semiconductor substrate. Transferring includes reducing and transferring.

The reflective mask has a conductive film on the opposite side of the multilayer reflective film from the substrate. The conductive film is used, for example, to absorb the reflective mask into an electrostatic chuck in exposure equipment. The conductive film of the reflective mask disclosed in Patent Document 1 has a coefficient of static friction of 0.25 or more measured in the atmosphere. It is stated that if the coefficient of static friction is 0.25 or higher, the positional deviation of the reflective mask can be suppressed even if the electrostatic chuck moves at high speed.

### CITATION LIST

### Patent Document

Patent Document 1: PCT International Publication No. 2016/204051

### SUMMARY OF INVENTION

### Technical Problem

The conductive film of the reflective mask can be abraded by contact with the electrostatic chuck of the exposure equipment. As a result, particles could occur. The particles get caught between the electrostatic chuck and the reflective mask, causing the reflective mask to deform. As a result, transfer accuracy of the EUVL could sometimes be degraded.

An aspect of the present disclosure is directed to providing a technique for suppressing abrasion of a conductive film due to contact with an electrostatic chuck of exposure equipment.

### Solution to Problem

A reflective mask blank according to an aspect of the present disclosure has a substrate, a multilayer reflective film configured to reflect EUV light, and an absorbing film configured to absorb the EUV light, in this order, and has a conductive film on an opposite side of the multilayer reflective film from the substrate. A coefficient of dynamic friction of the conductive film on the surface opposite from the substrate is less than 0.45, measured in a nitrogen atmosphere at room temperature.

### Advantageous Effects of Invention

According to the aspect of the present disclosure, it is possible to suppress abrasion of the conductive film due to contact with the electrostatic chuck of the exposure equipment.

### BRIEF DESCRIPTION OF DRAWINGS

FIG. 1 is a cross-sectional view showing a reflective mask blank according to an embodiment.

FIG. 2 is a flowchart showing a reflective mask blank manufacturing method according to an embodiment.

FIG. 3 is a cross-sectional view showing a reflective mask according to an embodiment.

FIG. 4 is a flowchart showing a reflective mask manufacturing method according to an embodiment.

FIG. 5A is a cross-sectional view showing an example of S201.

FIG. 5B is a cross-sectional view showing an example of S202.

FIG. 5C is a cross-sectional view showing an example of S203.

FIG. 6 is a cross-sectional view showing an example of EUV light reflected by the reflective mask of FIG. 3.

FIG. 7 is a cross-sectional view showing an example of the reflective mask and an electrostatic chuck.

FIG. 8 is a cross-sectional view showing another example of the reflective mask and the electrostatic chuck.

FIG. 9 is a cross-sectional view showing an example of disposition of electrodes used for measurement of contact resistance.

FIG. 10 is a view showing an example of a relationship between a resistance, an inter-electrode distance, and a contact resistance.

### DESCRIPTION OF EMBODIMENTS

Hereinafter, an embodiment of the present invention will be described with reference to the accompanying drawings. In each drawing, the same or corresponding components are designated by the same reference signs, and descriptions may be omitted. In the specification, the term “to” indicating a numerical range means that the values before and after it are included as lower and upper limits. The numerical range includes a rounded range.

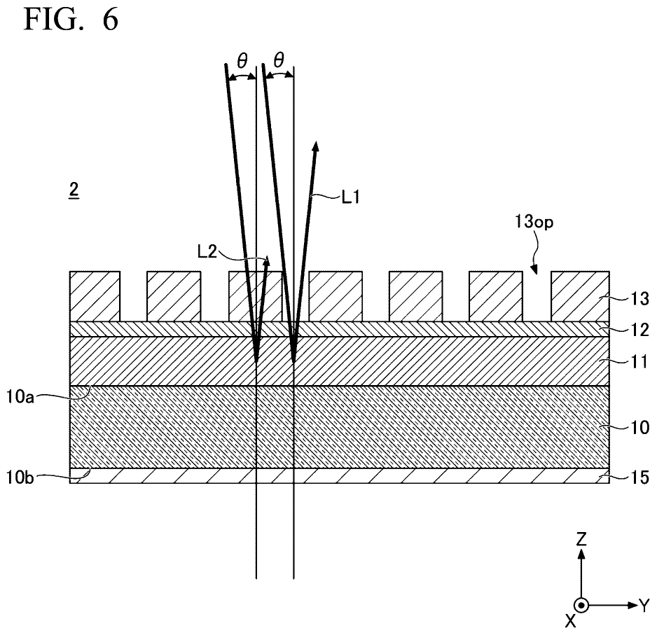

In each drawing, an X-axis direction, a Y-axis direction, and a Z-axis direction are perpendicular to each other. The Z-axis direction is a direction perpendicular to a first main surface 10a of a substrate 10. The X-axis direction is a direction perpendicular to an incidence surface of EUV light (a surface including incident rays and reflected rays). As shown in FIG. 6, the incident rays are tilted in a positive Y-axis direction as they move in a negative Z-axis direction, and the reflected rays are tilted in the positive Y-axis direction as they move in a positive Z-axis direction.

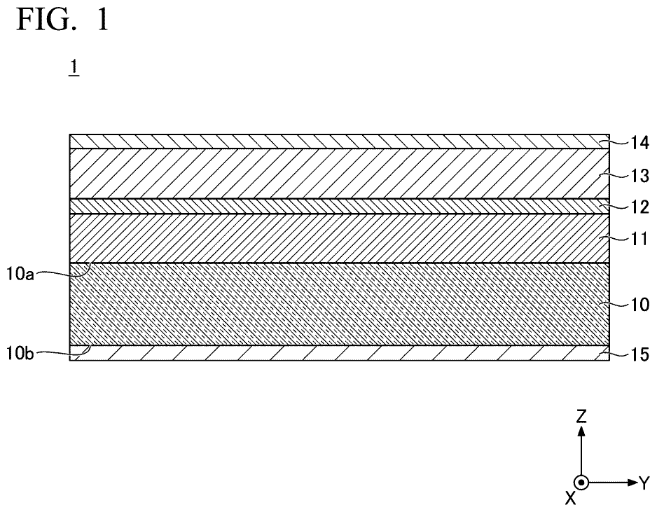

Referring to FIG. 1, a reflective mask blank 1 according to the embodiment will be described. The reflective mask blank 1 has, for example, the substrate 10, a multilayer reflective film 11, a protective film 12, an absorbing film 13, and a hard mask film 14, in this order. The multilayer reflective film 11, the protective film 12, the absorbing film 13, and the hard mask film 14 are formed on the first main surface 10a of the substrate 10, in this order. The multilayer reflective film 11 reflects EUV light. The protective film 12 protects the multilayer reflective film 11 from a first etching gas during the processing of the absorbing film 13. The absorbing film 13 absorbs the EUV light. The absorbing film 13 not only absorbs EUV light, but may also shift the phase of the EUV light. That is, the absorbing film 13 may be a phase shift film. The hard mask film 14 protects a portion of the absorbing film 13 from the first etching gas during processing of the absorbing film 13.

The reflective mask blank 1 has a conductive film 15 on the opposite side of the substrate 10 from the multilayer reflective film 11. That is, the reflective mask blank 1 may have, the conductive film 15, the substrate 10, the multilayer reflective film 11, the protective film 12, the absorbing film 13, and the hard mask film 14, in this order. The conductive film 15 is formed on a second main surface 10b of the substrate 10. The second main surface 10b is a surface facing opposite to the first main surface 10a. The conductive film 15 is used to adsorb a reflective mask 2 onto an electrostatic chuck of exposure equipment.

The reflective mask blank 1 may further have a functional film, which is not shown in FIG. 1. For example, the reflective mask blank 1 may have a diffusion barrier film (not shown) between the multilayer reflective film 11 and the protective film 12. The diffusion barrier film prevents metal elements contained in the protective film 12 from diffusing into the multilayer reflective film 11.

The reflective mask blank 1 may have, while not shown, a buffer film between the protective film 12 and the absorbing film 13. The buffer film protects the protective film 12 from the first etching gas, which forms an opening pattern 13op in the absorbing film 13. The buffer film is etched more slowly than the absorbing film 13. Unlike the protective film 12, the buffer film will ultimately have an opening pattern identical to the opening pattern 13op of the absorbing film 13.

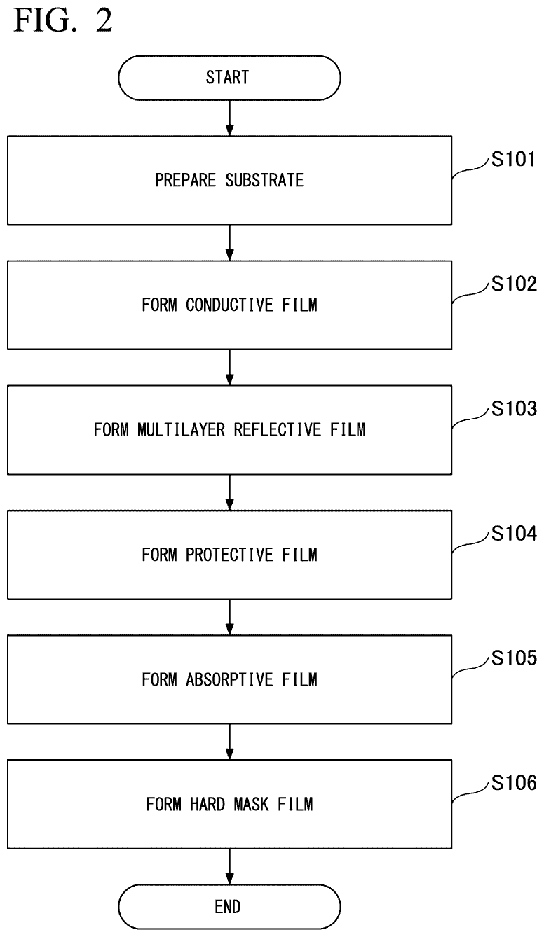

Next, referring to FIG. 2, a method of manufacturing the reflective mask blank 1 according to the embodiment will be described. The method of manufacturing the reflective mask blank 1 has, for example, steps S101 to S106 shown in FIG. 2. In step S101, the substrate 10 is prepared. In step S102, the conductive film 15 is formed on the second main surface 10b of the substrate 10. In step S103, the multilayer reflective film 11 is formed on the first main surface 10a of the substrate 10. In step S104, the protective film 12 is formed on the multilayer reflective film 11. In step S105, the absorbing film 13 is formed on the protective film 12. In step S106, the hard mask film 14 is formed on the absorbing film 13.

Further, the order of steps S101 to S106 is not limited to the order shown in FIG. 2. For example, the order of step S102 and steps S103 to S106 may be reversed. In addition, the method of manufacturing the reflective mask blank 1 does not necessarily have to include all of steps S101 to S106. The method of manufacturing the reflective mask blank 1 may further have a step of forming a functional film, which is not shown in FIG. 2.

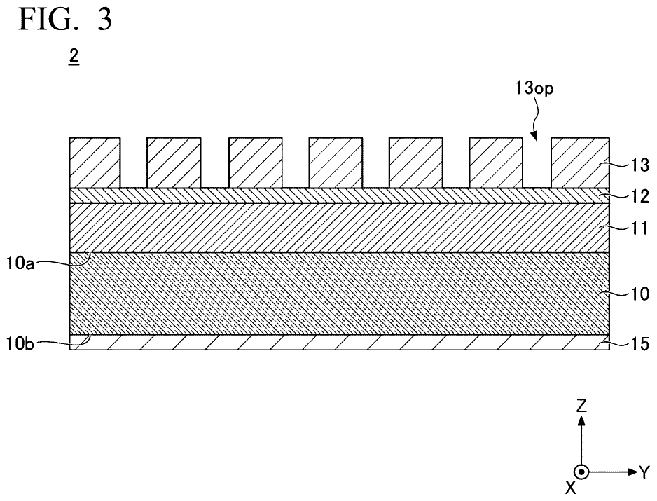

Next, referring to FIG. 3, the reflective mask 2 according to the embodiment will be described. The reflective mask 2 is equipped with, for example, the reflective mask blank 1 shown in FIG. 1 and includes the opening pattern 13op in the absorbing film 13. In the EUVL, the opening pattern 13op of the absorbing film 13 is transferred to a target substrate such as a semiconductor substrate or the like. Transferring includes reduction transfer. Further, the hard mask film 14 shown in FIG. 1 is not included in the reflective mask 2.

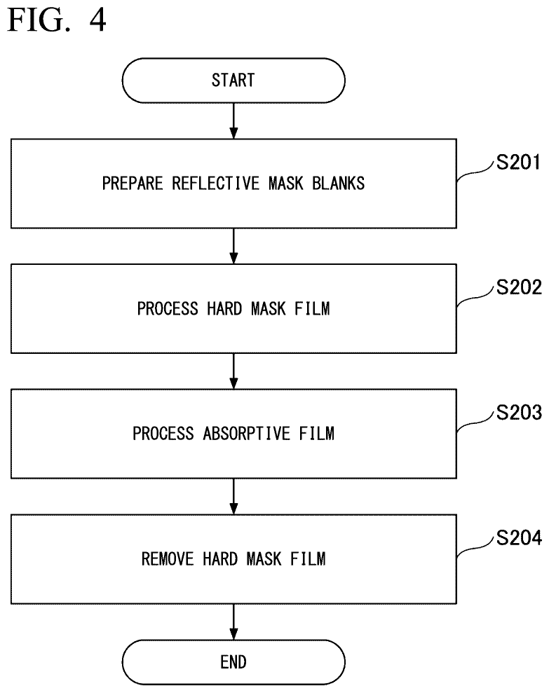

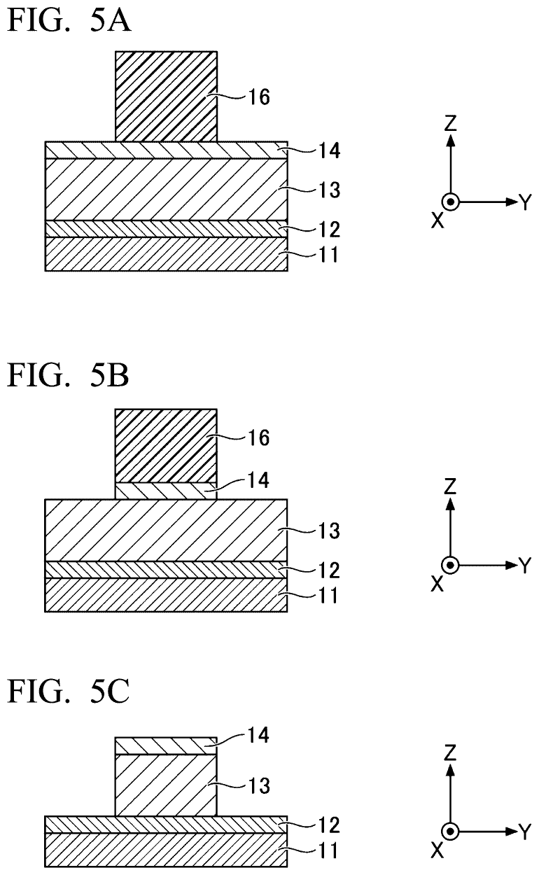

Next, referring to FIG. 4 to FIG. 5C, a method of manufacturing the reflective mask 2 according to the embodiment will be described. The method of manufacturing the reflective mask 2 has steps S201 to S204 shown in FIG. 4. In step S201, as shown in FIG. 5(A), the reflective mask blank 1 is prepared. As shown in FIG. 5A, the reflective mask blank 1 includes a resist film 16. The resist film 16 is formed on the hard mask film 14. The resist film 16 has an opening pattern formed thereon that is to be transferred to the absorbing film 13.

In step S202, as shown in FIG. 5B, the hard mask film 14 is processed using the resist film 16 having the opening pattern. In the opening of the resist film 16, the hard mask film 14 is exposed to a second etching gas, which etches the hard mask film 14. At the end of step S202, the resist film 16 remains. As a result, the opening pattern of the resist film 16 is transferred to the hard mask film 14.

The second etching gas is selected depending on the combination of the material of the resist film 16 and the material of the hard mask film 14, and includes, but is not limited to, for example, fluorine-based gases. The fluorine-based gas includes at least one selected from, for example, CF₄ gas, CHF₃ gas, C₂F₆ gas, C₃F₆ gas, C₄F₆ gas, C₄F₈ gas, CH₂F₂ gas, CH₃F gas, C₃F₈ gas, F₂ gas, SF₆ gas and NF₃ gas. The second etching gas may include an active gas or an inert gas in addition to a fluorine-based gas. The active gas includes, for example, at least one selected from O₂ gas and O₃ gas. The inert gas includes, for example, at least one selected from N₂ gas, He gas, and Ar gas. The second etching gas is preferably plasma-activated.

In step S203, as shown in FIG. 5C, the absorbing film 13 is processed using the hard mask film 14 having the opening pattern. In the opening of the hard mask film 14, the absorbing film 13 is exposed to a first etching gas, which etches the absorbing film 13. The hard mask film 14 has a higher resistance to the first etching gas than the absorbing film 13. At the end of step S203, the hard mask film 14 remains. As a result, the opening pattern of the hard mask film 14 is transferred to the absorbing film 13.

The first etching gas is selected depending on the combination of the material of the hard mask film 14 and the material of the absorbing film 13, and includes, but is not limited to, for example, a chlorine-based gas and an oxygen-based gas. The chlorine-based gas includes at least one selected from, for example, Cl₂ gas, SiCl₄ gas, CHCl₃ gas, CCl₄ gas and BCl₃ gas. The oxygen-based gas includes at least one selected from, for example, O₂ gas and O₃ gas. The first etching gas may include an inert gas, in addition to the chlorine-based gas and the oxygen-based gas. The inert gas includes at least one selected from, for example, N₂ gas, He gas and Ar gas. The first etching gas is preferably plasma-activated.

In step S204, while not shown, the hard mask film 14 is removed. For example, a third etching gas is used to remove the hard mask film 14. The third etching gases include, for example, fluorine-based gases, like the second etching gas. The third etching gas is preferably plasma-activated. A chemical solution may be used to remove the hard mask film 14.

Next, referring to FIG. 1 again, the substrate 10, the multilayer reflective film 11, the protective film 12, the absorbing film 13, the hard mask film 14, and the conductive film 15 will be described in this order.

The substrate 10 is, for example, a glass substrate. The material of the substrate 10 is preferably quartz glass containing TiO₂. Quartz glass has a smaller linear expansion coefficient and a smaller dimensional change due to temperature change than common soda lime glass. The quartz glass may contain 80 mass % to 95 mass % SiO₂, and 4 mass % to 17 mass % TiO₂. When a TiO₂ content is 4 mass % to 17 mass %, the linear expansion coefficient is almost zero near room temperature, and almost no dimensional change occurs near room temperature. The quartz glass may contain a third component or impurities other than SiO₂ and TiO₂. Further, the material of the substrate 10 may be crystallized glass in which a β-quartz solid solution is precipitated, silicon, or metal, etc.

The substrate 10 has the first main surface 10a and the second main surface 10b facing opposite to the first main surface 10a. The multilayer reflective film 11 or the like is formed on the first main surface 10a. When seen in a plan view (in the Z-axis direction), the size of the substrate 10 is, for example, 152 mm in height and 152 mm in width. The vertical dimension and the lateral dimension may be 152 mm or more. The first main surface 10a and the second main surface 10b each have, for example, a square quality assurance area in the center. The size of the quality assurance area is, for example, 142 mm in height and 142 mm in width. The vertical dimension and the lateral dimension may be 142 mm or more. A quality assurance area of the first main surface 10a preferably has a root mean square roughness (Rq) of 0.15 nm or less, and flatness of 100 nm or less. In addition, it is preferable that the quality assurance area of the first main surface 10a do not have any defects that cause phase defects.

The multilayer reflective film 11 reflects the EUV light. The multilayer reflective film 11 is, for example, a laminate of high refractive index layers and low refractive index layers alternately. The material of the high refractive index layer is, for example, silicon (Si), and the material of the low refractive index layer is, for example, molybdenum (Mo), and a Mo/Si multilayer reflective film is used. Further, a Ru/Si multilayer reflective film, a Mo/Be multilayer reflective film, a Mo compound/Si compound multilayer reflective film, a Si/Mo/Ru multilayer reflective film, a Si/Mo/Ru/Mo multilayer reflective film, a Si/Ru/Mo/Ru multilayer reflective film, a Si/Ru/Mo multilayer reflective film, or the like, is also usable as the multilayer reflective film 11.

The film thickness of each layer constituting the multilayer reflective film 11 and the number of repeating units of each layer can be selected appropriately depending on the material of each layer and its reflectivity to EUV light. When the multilayer reflective film 11 is a Mo/Si multilayer reflective film, in order to achieve a reflectivity of 60% or more for EUV light at an incidence angle θ (see FIG. 6) of 6°, a Mo layer with a film thickness of 2.3±0.1 nm and a Si layer with a film thickness of 4.5±0.1 nm can be laminated so that the number of repeating units is 30 or more and 60 or less. The multilayer reflective film 11 preferably has a reflectivity of 60% or more for EUV light when the incidence angle θ is 6°. The reflectivity is preferably 65% or more.

The film forming method for each layer constituting the multilayer reflective film 11 is, for example, a DC sputtering method, a magnetron sputtering method, or an ion beam sputtering method. When forming the Mo/Si multilayer reflective film using the ion beam sputtering method, an example of the film forming conditions for each of the Mo layer and the Si layer is as follows.

### <Film Forming Conditions of Si Layer>

Target: Si target,
Sputter gas: Ar gas,
Gas pressure: 1.3×10⁻² Pa to 2.7×10⁻² Pa,
Ion acceleration voltage: 300V to 1500V,
Film forming speed: 0.030 nm/sec to 0.300 nm/sec,
Film thickness of Si layer: 4.5=0.1 nm,

### <Film Forming Conditions of Mo Layer>

Target: Mo target,
Sputter gas: Ar gas,
Gas pressure: 1.3×10⁻² Pa to 2.7×10⁻² Pa,
Ion acceleration voltage: 300V to 1500V,
Film forming speed: 0.030 nm/sec to 0.300 nm/sec,
Film thickness of Mo layer: 2.3±0.1 nm,

### <Repeating Unit of Si Layer and Mo Layer>

Repeating unit number: 30 to 60 (preferably 40 to 50).

The protective film 12 is formed between the multilayer reflective film 11 and the absorbing film 13 to protect the multilayer reflective film 11. The protective film 12 protects the multilayer reflective film 11 from the first etching gas during the processing of the absorbing film 13, i.e., step S203. The protective film 12 is not removed by exposure to the first etching gas, but remains on top of the multilayer reflective film 11.

The protective film 12 contains at least one element selected from, for example, Ru, Rh and Si. When the protective film 12 contains Rh, it may contain only Rh or may contain an Rh compound. The Rh compound may contain, in addition to Rh, at least one element selected from the group consisting of Ru, Nb, Mo, Ta, Ir, Pd, Zr, Y and Ti.

The Rh compound may contain at least one element selected from the group consisting of N, O, C and B in addition to Rh. These elements reduce the resistance of the protective film 12 to the first etching gas, but they also improve the smoothness of the protective film 12 by reducing crystallinity of the protective film 12. When the Rh compound has an amorphous structure or a microcrystalline structure, the X-ray diffraction profile of the Rh compound does not have a clear peak.

In the embodiment, the protective film 12 is a single layer film consisting of a single layer, but it may also be a multilayer film having a lower layer and an upper layer. The lower layer of the protective film 12 is a layer formed in contact with the uppermost layer of the multilayer reflective film 11. The upper layer of the protective film 12 is in contact with the lowermost layer of the absorbing film 13. In this way, by making the protective film 12 a multilayer structure, materials with excellent specific functions can be used for each layer, making the entire protective film 12 multifunctional.

The upper layer of the protective film 12 preferably contains at least one element selected from Ru and Rh, more preferably contains Rh, and even more preferably contains an Rh compound. The lower layer of the protective film 12 preferably contains at least one element selected from Ru, Rh, Nb, Mo, Zr, Y and Si, and more preferably contains Ru. In addition, in order to suppress the crystallinity of the protective film 12, the lower layer of the protective film 12 preferably contains at least one element selected from C, N and B in addition to the at least one element described above. If the protective film 12 is a multilayer film, the thickness of the protective film 12 below refers to the total film thickness of the multilayer film. Further, a mixing layer formed by mixing the components contained in the multilayer reflective film 11 and the lower layer of the protective film 12 may be formed between the multilayer reflective film 11 and the lower layer of the protective film 12.

The thickness of the protective film 12 is preferably 1.0 nm to 4.0 nm, more preferably 2.0 nm to 3.5 nm, and even more preferably 2.5 nm to 3.0 nm. If the thickness of the protective film 12 is 1.0 nm or more, the etching resistance is good. In addition, if the thickness of the protective film 12 is 4.0 nm or less, the reflectivity to EUV light is good.

The density of the protective film 12 is preferably 10.0 g/cm³ to 14.0 g/cm³. If the density of the protective film 12 is 10.0 g/cm³ or higher, it has good etching resistance. In addition, if the density of the protective film 12 is 14.0 g/cm³ or less, the decrease in reflectivity to EUV light can be suppressed.

The film forming method of the protective film 12 is, for example, a DC sputtering method, a magnetron sputtering method, an ion beam sputtering method, or the like. When forming an Rh film using the DC sputtering method, an example of the film forming conditions is as follows.

### <Film Forming Conditions of Rh Film>

Target: Rh target,
Sputter gas: Ar gas,
Gas pressure: 1.0×10⁻² Pa to 1.0×10⁰ Pa,
Output density of target: 1.0 W/cm² to 8.5 W/cm²,
Film forming speed: 0.020 nm/sec to 1.000 nm/sec,
Film thickness: 1 nm to 10 nm.

The absorbing film 13 absorbs EUV light. The absorbing film 13 is the film on which the opening pattern 13op is to be formed. The opening pattern 13op is not formed in the manufacturing process of the reflective mask blank 1, but is formed in the manufacturing process of the reflective mask 2. The absorbing film 13 not only absorbs EUV light, but may also shift the phase of the EUV light. That is, the absorbing film 13 may be a phase shift film. The phase shift film shifts the phase of the second EUV light L2 relative to the first EUV light L1 shown in FIG. 6.

The first EUV light L1 is light that passes through the opening pattern 13op of the absorbing film 13 without being absorbed by the absorbing film 13, is reflected by the multilayer reflective film 11, and passes through the opening pattern 13op of the absorbing film 13 again without being absorbed by the absorbing film 13. The second EUV light L2 is light that is absorbed by the absorbing film 13 while passing through the absorbing film 13, reflected by the multilayer reflective film 11, and then absorbed by the absorbing film 13 again while passing through the absorbing film 13.

The phase difference (≥0) between the first EUV light L1 and the second EUV light L2 is, for example, 170° to 250°. The phase of the first EUV light L1 may be ahead of or behind the phase of the second EUV light L2. The absorbing film 13 utilizes the interference between the first EUV light L1 and the second EUV light L2 to improve the contrast of the transferred image. The transferred image is the image of the opening pattern 13op of the absorbing film 13 transferred to the target substrate.

In the EUVL, a so-called projection effect (shadowing effect) is generated. The shadowing effect occurs when the incidence angle θ of EUV light is not 0° (for example, 6°), resulting in a region near the sidewall of the opening pattern 13op that blocks EUV light, causing positional or dimensional deviation in the transferred image. To reduce the shadowing effect, it is effective to lower the sidewall height of the opening pattern 13op and to make the absorbing film 13 thinner.

The film thickness of the absorbing film 13 is, for example, 60 nm or less, preferably 50 nm or less, in order to reduce the shadowing effect. The film thickness of the absorbing film 13 is preferably 20 nm or more, more preferably 30 nm or more, to ensure a phase difference between the first EUV light L1 and the second EUV light L2.

In order to reduce the film thickness of the absorbing film 13 to reduce the shadowing effect while maintaining the phase difference between the first EUV light L1 and the second EUV light L2, it is effective to reduce a refractive index n of the absorbing film 13. In addition, increasing the extinction coefficient k of the absorbing film 13 is effective in reducing the reflectivity for the second EUV light L2. In this way, the absorbing film 13 is required to have excellent optical properties.

The absorbing film 13 preferably contains at least one metal element selected from Cr, Ta, Nb, Ir, Pt, Co, Ni, Cu, Sn, Pd, Os, Re, Au and Ru. These metal elements have a relatively low refractive index, so the thickness of the absorbing film 13 can be reduced while maintaining a phase difference. The absorbing film 13 preferably contains a compound of metal elements. The compound of the metal elements preferably contains at least one element selected from O, B, C and N. By adding at least one element selected from O, B, C and N, it is possible to suppress crystallization while suppressing the deterioration of optical properties, and to reduce the roughness of the opening pattern 13op.

In the embodiment, the absorbing film 13 is a single layer film constituted by a single layer, but it may also be a multilayer film having a lower layer and an upper layer. The lower and upper layers that constitute the absorbing film 13 are formed on the protective film 12 in this order. The uppermost layer of the absorbing film 13 is the layer farthest from the protective film 12. The uppermost layer of the absorbing film 13 preferably contains at least one metal element selected from Cr, Ta, Nb, Ir, Pt, Pd, Os, Re, Au, and Ru, and more preferably contains a compound of the metal elements. When the absorbing film 13 is a multilayer film, the thickness of the absorbing film 13 means the total film thickness of the multilayer film.

The film forming method of the absorbing film 13 is, for example, a DC sputtering method, a magnetron sputtering method, an ion beam sputtering method, or the like. The nitrogen content of the absorbing film 13 can be controlled by the N₂ gas content in the sputter gas.

When a TaN film is formed using the reactive sputtering method, an example of the film forming conditions is as follows.

### <Film Forming Conditions of TaN Film>

Target: Ta target,
Output density of Ta target: 1.0 W/cm² to 8.5 W/cm²,
Sputter gas: mixed gas containing Ar gas and N₂ gas,
Volume ratio of N₂ gas in sputter gas (N₂/(Ar+N₂)): 0.01 to 0.25,
Gas pressure: 1.0×10⁻² Pa to 1.0×10⁰ Pa,
Output density of Ta target: 1.0 W/cm² to 8.5 W/cm²,
Film forming speed: 0.020 nm/sec to 0.060 nm/sec,
Film thickness: 20 nm to 60 nm.

The hard mask film 14 is formed on the opposite side of the absorbing film 13 from the protective film 12 and is used to form the opening pattern 13op on the absorbing film 13. The hard mask film 14 allows the resist film 16 to be thin.

The hard mask film 14 preferably includes at least one metal or semi-metal element selected from Al, Hf, Y, Cr, Nb, Ti, Mo, Ta and Si. The hard mask film 14 preferably contains a compound of the above-mentioned metal elements or semi-metal elements. Preferably, the compound contains at least one element selected from O, N, C and B.

The film thickness of the hard mask film 14 is preferably 2 nm or more and 30 nm or less, more preferably 2 nm or more and 25 nm or less, and even more preferably 2 nm or more and 10 nm or less.

The film forming method of the hard mask film 14 is, for example, a DC sputtering method, a magnetron sputtering method, an ion beam sputtering method, or the like.

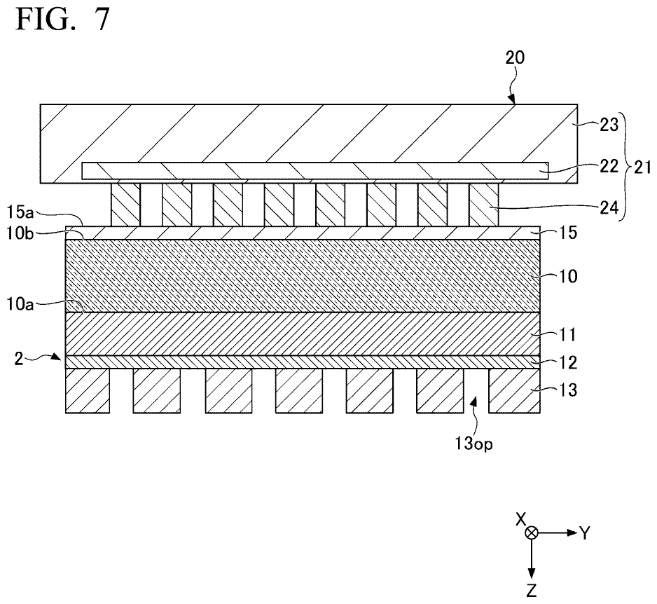

As shown in FIG. 7, the conductive film 15 is formed on the opposite side of the substrate 10 from the multilayer reflective film 11 and is used to absorb the reflective mask 2 onto an electrostatic chuck 21 of exposure equipment 20. The electrostatic chuck 21 has an electrode 22 that generates an electrostatic adsorption force, an insulating stage 23 in which the electrode 22 is embedded, and a plurality of insulating burls 24 protruding from a stage 23. The plurality of burls 24 contact the conductive film 15. The plurality of burls 24 are each cylindrical in the embodiment, but may also be tapered conical.

The electrostatic chuck 21 repeatedly adsorbs and releases the reflective mask 2 for the purpose of maintenance or replacement of the reflective mask 2. It is preferable that the conductive film 15 of the reflective mask 2 has a coefficient of dynamic friction of less than 0.45 on a surface 15a opposite the substrate 10, measured in a nitrogen atmosphere at room temperature (for example, 25° C.), so that it is not abraded by contact with the burls 24 of the electrostatic chuck 21.

The coefficient of dynamic friction can generally be measured more accurately than the coefficient of static friction. The measurement atmosphere for the coefficient of dynamic friction is the nitrogen atmosphere. The absolute humidity in the nitrogen atmosphere is 10% or less. The coefficient of dynamic friction is measured in a nitrogen atmosphere because the atmosphere inside the exposure equipment 20 is a vacuum atmosphere with low vapor concentration. Since it is difficult to measure the coefficient of dynamic friction in a vacuum atmosphere, the next best option is to measure the coefficient of dynamic friction in a nitrogen atmosphere. Further, in the atmosphere, the surface condition of the conductive film 15 changes due to the influence of moisture, which may cause unstable measurement results.

The coefficient of dynamic friction of the surface 15a of the conductive film 15 is measured using, for example, a TRB3 manufactured by Anton Paar GmbH. An indenter to be pressed against the surface 15a of the conductive film 15 is a stainless steel sphere with a diameter of 10 mm, on the surface of which a TiN film is formed. The TiN film is a material used in the burls 24. The load pressing the indenter against the surface 15a of the conductive film 15 is, for example, 0.25 N. The coefficient of dynamic friction is calculated as an average value when the indenter moves back and forth four times on the same straight line.

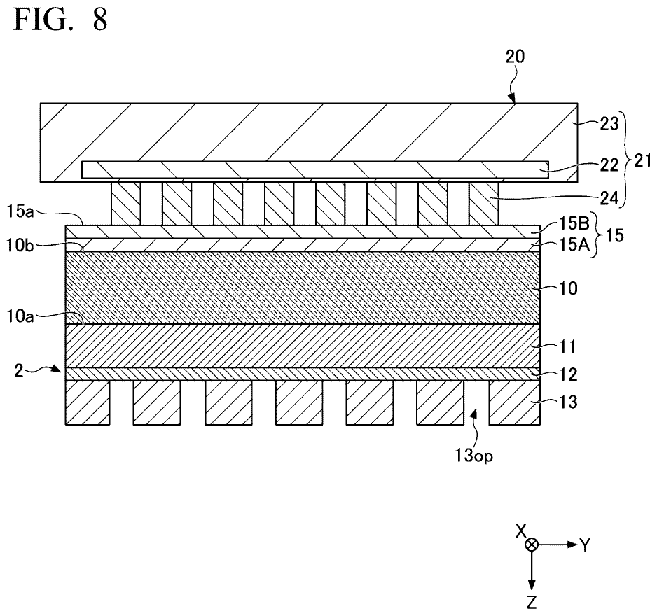

In the embodiment, the conductive film 15 is a single layer film constituted by a single layer, but it may also be a multilayer film having a lower layer 15A and an upper layer 15B as shown in FIG. 8. The conductive film 15 is constituted by the lower layer 15A and the upper layer 15B, which are formed on the substrate 10 in this order. The lower layer 15A is in contact with the substrate 10. The upper layer 15B is in contact with the plurality of burls 24.

Further, the lower layer 15A of the conductive film 15 does not have to be in contact with the substrate 10, and another functional film may be formed between the conductive film 15 and the substrate 10. The conductive film 15 may have an intermediate layer between the lower layer 15A and the upper layer 15B.

When the conductive film 15 is a multilayer film, after all layers constituting the conductive film 15 are formed on the substrate 10, the coefficient of dynamic friction of the surface 15a of the conductive film 15 is measured. That is, when the conductive film 15 is a multilayer film, the coefficient of dynamic friction of the surface 15a of the upper layer 15B opposite the substrate 10 is measured.

If the coefficient of dynamic friction of the surface 15a of the conductive film 15 measured in a nitrogen atmosphere at room temperature is less than 0.45, the friction force between the conductive film 15 and the burls 24 is sufficiently low. Therefore, abrasion of the conductive film 15 can be suppressed, and the generation of particles can be suppressed. The particles get caught between the electrostatic chuck 21 and the reflective mask 2, causing the reflective mask 2 to deform. As a result, transfer accuracy of EUVL could sometimes be degraded. According to the embodiment, it is possible to suppress the generation of particles and improve the transfer accuracy of EUVL.

The coefficient of dynamic friction of the surface 15a of the conductive film 15, measured in a nitrogen atmosphere at room temperature, is preferably less than 0.45, more preferably 0.40 or less, and even more preferably 0.35 or less. Further, the coefficient of dynamic friction of the surface 15a of the conductive film 15 measured in a nitrogen atmosphere at room temperature is preferably 0.10 or more, and more preferably 0.15 or more.

When the conductive film 15 is a single layer film, it is preferable that the conductive film 15 contains at least one metal element selected from Cr and Ta from the viewpoints of conductivity and stability. The conductive film 15 preferably contains a compound of the above-mentioned metal elements. The compound preferably contains at least one non-metal element selected from N, O, C, B and Si. The oxygen content of the compound is preferably 30 at % or less.

When the conductive film 15 is a multilayer film, the lower layer 15A preferably contains at least one metal element selected from Cr and Ta from the viewpoints of conductivity and stability. The lower layer 15A preferably contains a compound of the above-mentioned metal elements. The compound preferably contains at least one non-metal element selected from N, C, B and Si from the viewpoint of conductivity and film stress adjustment. Among these non-metallic elements, N is the most preferable from the viewpoint of adjusting the film stress. By adjusting the film stress, the warping of the reflective mask 2 can be reduced. The N content of the lower layer 15A is preferably 5 at % or more, and more preferably 10 at % or more. In addition, the N content of the lower layer 15A is preferably 40 at % or less, and more preferably 30 at % or less. From the viewpoint of conductivity, it is preferable that the lower layer 15A contains substantially no O. The O content of the lower layer 15A is preferably 0.1 at % or less.

The content of each element in the conductive film 15 adopts a value obtained through analysis by X-ray photoelectron spectroscopy (XPS). The detailed content analysis method follows the method described in the examples below. When the conductive film 15 has a multi-layer structure, for example, analysis is performed while etching the conductive film 15 from the surface opposite the substrate 10 using ion sputtering of argon or the like, and the content of each element in each layer of the conductive film 15 is analyzed.

When the conductive film 15 is a multilayer film and the lower layer 15A contains Ta and N, the Ta content is preferably 60 at % or more, more preferably 65 at % or more, and even more preferably 70 at % or more. In addition, the Ta content is preferably 95 at % or less, more preferably 90 at % or less, even more preferably 85 at % or less, and particularly preferably 80 at % or less.

When the conductive film 15 is a multilayer film and the lower layer 15A contains Cr and N, the Cr content is preferably 75 at % or more, more preferably 80 at % or more, and even more preferably 85 at % or more. In addition, the Cr content is preferably 95 at % or less, and more preferably 93 at % or less.

When the conductive film 15 is a multilayer film, the upper layer 15B is preferably formed of a material having a smaller coefficient of dynamic friction than the lower layer 15A, and preferably contains 5 at % or more of O (oxygen). Since O is chemically stable, the coefficient of dynamic friction is small. The O content is preferably 5 at % or more, more preferably 10 at % or more, and even more preferably 15 at % or more. The O content is preferably 60 at % or less, more preferably 55 at % or less, even more preferably 50 at % or less, and particularly preferably 45 at % or less. It is preferable that the upper layer 15B contains substantially no N, from the viewpoint of reducing the coefficient of dynamic friction. The N content of the upper layer 15B is preferably 0.1 at % or less.

When the conductive film 15 is a multilayer film and the upper layer 15B contains Ta and O, the Ta content is preferably 45 at % or more, more preferably 50 at % or more, and even more preferably 55 at % or more. In addition, the Ta content is preferably 80 at % or less, more preferably 75 at % or less, even more preferably 70 at % or less, and particularly preferably 65 at % or less.

When the conductive film 15 is a multilayer film and the upper layer 15B contains Cr and O, the Cr content is preferably 65 at % or more, more preferably 70 at % or more, and even more preferably 75 at % or more. In addition, the Cr content is preferably 95 at % or less, more preferably 90 at % or less, and even more preferably 85 at % or less.

When the conductive film 15 is a multilayer film, the upper layer 15B preferably contains at least one metal element selected from Cr and Ta, from the viewpoint of adhesion between the upper layer 15B and the lower layer 15A. The upper layer 15B and the lower layer 15A more preferably contain the same metal element. For example, more preferably, both the upper layer 15B and the lower layer 15A contain Cr. Alternatively, more preferably, both the upper layer 15B and the lower layer 15A contain Ta. Both the upper layer 15B and the lower layer 15A may contain Cr and Ta.

When the conductive film 15 is a multilayer film, the upper layer 15B preferably has a thickness of 4 nm or more. As the thickness of the upper layer 15B, which is more slippery than the lower layer 15A, is increased, the abrasion of the conductive film 15 can be reduced. The thickness of the upper layer 15B is preferably 4 nm or more, and more preferably 6 nm or more. However, the upper layer 15B has lower conductivity than the lower layer 15A. Here, from the viewpoint of the conductivity of the conductive film 15, the thickness of the upper layer 15B is preferably 50 nm or less, and more preferably 30 nm or less.

The contact resistance of the conductive film 15 is preferably 1000×10⁻³ Ωcm² or less, more preferably 500×10⁻³ Ωcm² or less, and even more preferably 300×10⁻³ Ωcm² or less.

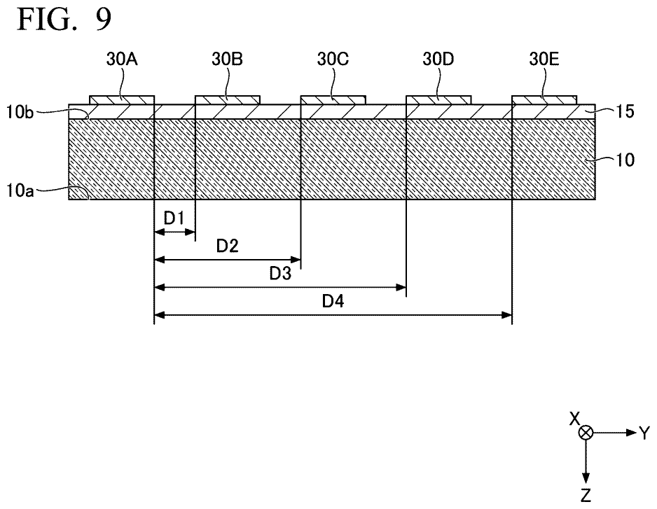

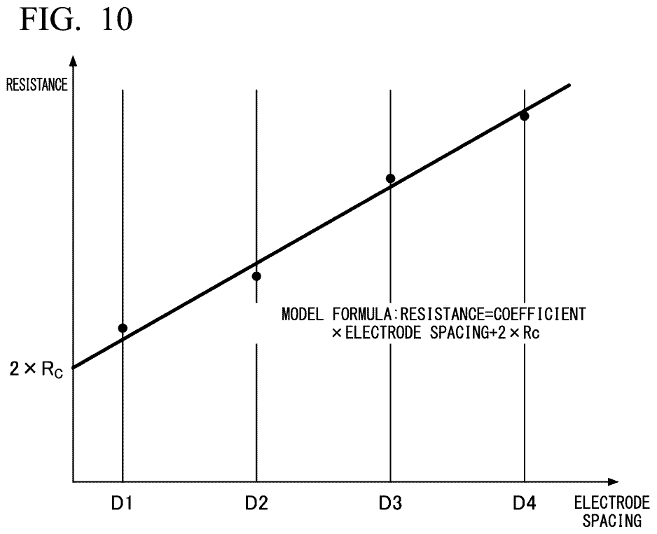

As shown in FIG. 9, the contact resistance of the conductive film 15 is determined by arranging five 1.2 mm diameter disk electrodes 30A, 30B, 30C, 30D, and 30E in a line with a 2.0 mm pitch and measuring the resistance at inter-electrode distances D1, D2, D3, and D4. D1 is 0.8 mm, D2 is 2.8 mm, D3 is 4.8 mm, and D4 is 6.8 mm. As shown in FIG. 10, a regression line is obtained using the least squares method. The regression line model is shown in FIG. 10. By dividing the intercept of the regression line (2×R_{C}) by 2 and multiplying it by a contact area(S) of one disk electrode and the conductive film 15, the contact resistance (ρ_{C}) is obtained (ρ_{C}=R_{C}×S).

The film thickness of the conductive film 15 is preferably 50 nm to 400 nm, and more preferably 70 nm to 350 nm. When the conductive film 15 is a multilayer film, the film thickness of the conductive film 15 is the total thickness of the multilayer film.

The film forming method of the conductive film 15 is, for example, a DC sputtering method, a magnetron sputtering method, an ion beam sputtering method, or the like.

[Examples] Hereinafter, experimental data will be described. In Examples 1 to 5, the conductive film 15 was formed on the substrate 10 under the film forming conditions shown in Table 1. Examples 1 to 3 are embodiments, and Examples 4 and 5 are comparative examples.

As a substrate, a SiO₂—TiO₂ glass substrate (6 inch (152 mm) square, 6.3 mm thick) was prepared. The glass substrate had a thermal expansion coefficient of 0.02×10⁻⁷/° C. at 20° C., a Young's modulus of 67 GPa, a Poisson's ratio of 0.17, and a specific stiffness of 3.07×10⁷ m²/s².

In Example 1, as shown in Table 1, a CrN film was deposited as a lower layer by a magnetron sputtering method, and then a CrO film was deposited as an upper layer by a magnetron sputtering method. The film-forming conditions for the CrN film and the CrO film were as follows:

### <Film Forming Condition of CrN Film>

Target: Cr target,
Sputter gas: mixed gas containing Ar gas 57 vol % and N₂ gas 43 vol %,
Gas pressure: 0.10 Pa,
Input power density: 4.6 W/cm².

### <Film Forming Condition of CrO Film>

Target: Cr target,
Sputter gas: mixed gas containing Kr gas 40 vol % and O₂ gas 60 vol %,
Gas pressure: 0.10 Pa,
Input power density: 4.1 W/cm².

### (Conductive Film Composition)

The composition of the conductive film 15 was analyzed by the XPS. For the XPS, “PHI 5000 VersaProbe” manufactured by ULVAC-PHI Inc. was used. The composition determined by analysis is shown in Table 1 below.

### (Film Thickness)

The film thickness of the conductive film 15 was measured using X-ray reflectivity (XRR). For the XRR measurements, a Smart Lab HTP manufactured by Rigaku Company was used. The X-ray source used was CuKα radiation, with a tube voltage of 40 kV and a tube current of 30 mA. The analysis was performed using the accompanying software (GlobalFit).

### (Contact Resistance)

The contact resistance of the conductive film 15 was measured using the method described above.

In Examples 2 to 5, the conductive film 15 was formed on the substrate 10 under the same conditions except that the film forming conditions were changed as shown in Table 1.

TABLE 1

| | | Ex. 1 | | Ex. 2 | | Ex. 3 | | | |
|---|---|---|---|---|---|---|---|---|---|
| | | Multilayer | | Multilayer | | Multilayer | | Ex. 4 | Ex. 5 |
| | | Lower | Upper | Lower | Upper | Lower | Upper | Single | Single |
| Layer structure | | layer | layer | layer | layer | layer | layer | layer | layer |
| Film type | | CrN | CrO | TaN | CrO | TaN | TaO | TaB | CrN |
| Film thickness | | 360 | 20 | 30 | 28 | 70 | 10 | 70 | 360 |
| Film | Ar gas | 57 | 0 | 81 | 0 | 81 | 40 | 100 | 0 |
| forming | (vol %) | | | | | | | | |
| conditions | Kr gas | 0 | 40 | 0 | 40 | 0 | 0 | 0 | 60 |
| | (vol %) | | | | | | | | |
| | Xe gas | 0 | 0 | 0 | 0 | 0 | 0 | 0 | 0 |
| | (vol %) | | | | | | | | |
| | N₂ gas | 43 | 0 | 19 | 0 | 19 | 0 | 0 | 40 |
| | (vol %) | | | | | | | | |
| | O₂ gas | 0 | 60 | 0 | 60 | 0 | 60 | 0 | 0 |
| | (vol %) | | | | | | | | |
| | Gas | 0.10 | 0.10 | 0.23 | 0.10 | 0.23 | 0.05 | 0.12 | 0.10 |
| | pressure | | | | | | | | |
| | [Pa] | | | | | | | | |
| | Target | Cr | Cr | Ta | Cr | Ta | Ta | Ta₃B₂ | Cr |
| | Input | 4.6 | 4.1 | 2.6 | 4.1 | 2.6 | 2.7 | 6.9 | 4.6 |
| | power | | | | | | | | |
| | density | | | | | | | | |
| | [W/cm²] | | | | | | | | |
| Content | Ta | — | 80 | 71 | 80 | 71 | 60 | 77 | — |
| [at %] | Cr | 91 | — | — | — | — | — | — | 91 |
| | O | — | 20 | — | 20 | — | 40 | — | — |
| | B | — | — | — | — | — | — | 23 | — |
| | N | 9 | — | 29 | — | 29 | — | — | 9 |

| | | | | | |
|---|---|---|---|---|---|
| Coefficient of dynamic | 0.31 | 0.32 | 0.20 | 0.48 | 0.45 |
| friction in nitrogen | | | | | |
| atmosphere | | | | | |
| Abrasion evaluation | Good | Good | Good | Poor | Poor |
| Contact resistance | 10 or less | 10 or less | 210 | 10 or | 10 or |
| (×10⁻³ Ωcm²⁾ | | | | less | less |

After formation of the conductive film 15, both measurement of the coefficient of dynamic friction and the abrasion test were carried out in a nitrogen atmosphere. For the abrasion test, a TRB3 manufactured by Anton Paar GmbH was used, as was the measurement of the coefficient of dynamic friction. The indenter pressed against the surface 15a of the conductive film 15 was a stainless steel sphere with a diameter of 10 mm and a TiN film formed on its surface. The load pressing the indenter against the surface 15a of the conductive film 15 was 0.25N. In the abrasion test, after the indenter was moved back and forth 250 times along the same straight line, the surface of the conductive film 15 was observed under an optical microscope. In Table 1, abrasion evaluation of “Good” means that no delamination of the conductive film 15 was observed under an optical microscope during the abrasion test, and the abrasion evaluation of “Poor” means that delamination of the conductive film 15 was observed under an optical microscope during the abrasion test.

In Examples 1 to 3, unlike Examples 4 and 5, since the coefficient of dynamic friction of the surface 15a of the conductive film 15 measured in a nitrogen atmosphere at room temperature was less than 0.45, delamination of the conductive film 15 was not observed in the electron microscope photographs during the abrasion test. From this, Examples 1 to 3 are able to suppress abrasion of the conductive film 15 and reduce the generation of particles compared to Examples 4 to 5.

In the examples of the application, the coefficient of dynamic friction, etc. was evaluated for a substrate with a conductive film formed on it, but the estimation results for the coefficient of dynamic friction, etc. were similar when the conductive film was formed as part of the reflective mask blank.

Hereinabove, although the reflective mask blank, the reflective mask, the reflective mask blank manufacturing method, and the reflective mask manufacturing method according to the present disclosure has been described, the present disclosure is not limited to the above-mentioned embodiments. Within the scope of the claims, various changes, modifications, substitutions, additions, deletions, and combinations are possible. Naturally, these also fall within the technical scope of the present disclosure.

Priority is claimed on Japanese Patent Application No. 2023-201162, filed Nov. 29, 2023, the content of which is incorporated herein by reference.

### REFERENCE SIGNS LIST

1 Reflective mask blank
2 Reflective mask
10 Substrate
11 Multilayer reflective film
13 Absorbing film
15 Conductive film

1. A reflective mask blank comprising a substrate, a multilayer reflective film configured to reflect EUV light, and an absorbing film configured to absorb the EUV light in this order, and having a conductive film on the opposite side of the multilayer reflective film from the substrate,
wherein a coefficient of dynamic friction of the conductive film on the surface opposite the substrate is less than 0.45, measured in a nitrogen atmosphere at room temperature.

2. The reflective mask blank according to claim 1, wherein the conductive film has lower and upper layers with conductivity, the lower layer and the upper layer being formed on the substrate in this order, and
the upper layer has a coefficient of dynamic friction of less than 0.45 on the surface opposite the substrate, measured in a nitrogen atmosphere at room temperature.

3. The reflective mask blank according to claim 2, wherein the lower layer contains at least one metal element selected from Cr and Ta.

4. The reflective mask blank according to claim 2, wherein the upper layer contains 5 at % or more of O.

5. The reflective mask blank according to claim 2, wherein the upper layer has a thickness of 4 nm or more.

6. The reflective mask blank according to claim 2, wherein the lower layer contains at least one non-metal element selected from N, B, Si and C.

7. The reflective mask blank according to claim 2, wherein the upper layer contains at least one metal element selected from Cr and Ta.

8. The reflective mask blank according to claim 1, wherein a contact resistance of the conductive film is 1000×10⁻³ Ωcm² or less.

9. The reflective mask blank according to claim 1, wherein a film thickness of the conductive film is 50 nm to 400 nm.

10. A reflective mask comprising: the reflective mask blank according to claim 1 wherein the absorbing film includes an opening pattern.

11. A reflective mask blank manufacturing method comprising:
preparing a substrate having a first main surface and a second main surface facing opposite to the first main surface;
forming a multilayer reflective film that reflects EUV light and an absorbing film that absorbs EUV light on the first main surface of the substrate in this order; and
forming a conductive film on the second main surface of the substrate,
wherein a coefficient of dynamic friction of the conductive film on the surface opposite the substrate is less than 0.45, measured in a nitrogen atmosphere at room temperature.

12. A reflective mask manufacturing method comprising:
preparing the reflective mask blank according to claim 1; and
forming an opening pattern in the absorbing film, in this order.
